(19) United States
(12) Patent Application Publication
(10) Pub. No.: US 2007/0264814 A1
(43) Pub. Date: Nov. 15, 2007

(54) METHOD FOR FORMING METAL WIRING LINE, METHOD FOR MANUFACTURING ACTIVE MATRIX SUBSTRATE, DEVICE, ELECTRO-OPTICAL DEVICE, AND ELECTRONIC APPARATUS

(75) Inventors: Toshimitsu HIRAI, Chino (JP); Katsuyuki MORIYA, Azumino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/737,165

(22) Filed: Apr. 19, 2007

(30) Foreign Application Priority Data
May 12, 2006 (JP) 2006-133596
Dec. 11, 2006 (JP) 2006-332894

(51) Int. Cl. H01L 21/44

(52) U.S. Cl. 438/617

(57) ABSTRACT

A method for forming a metal wiring line, comprises: (a) forming a bank including a first opening corresponding to a first film pattern and a second opening corresponding to a second film pattern that is coupled to the first film pattern and has a width narrower than a width of the first film pattern; (b) disposing a droplet of a functional liquid in the first opening so as to dispose the functional liquid in the second opening by an autonomous flow of the functional liquid; (c) hardening the functional liquid disposed in the first opening and the second opening; and (d) forming the first film pattern and the second film pattern by alternately repeating step (b) and step (c) at least one time.

### BACKGROUND

1. Technical Field

The present invention relates to a method for forming a metal wiring line, a method for manufacturing an active matrix substrate, a device, an electro-optical device, and an electronic apparatus.

2. Related Art

As a method for forming a wiring line, which has a predetermined pattern and is used in electric circuits and integrated circuits, photolithography has been widely used. However, photolithography needs large-scale equipment such as vacuum apparatuses and exposure apparatuses, and cumbersome processes to form a wiring line having a predetermined pattern. In addition, almost all of materials are wasted due to a low efficiency of about several percent in using materials, resulting in high manufacturing costs.

Alternatively, a method is proposed in which a wiring line having a predetermined pattern is formed on a substrate using a droplet discharge method (called an inkjet method) in which a liquid material is discharged from a liquid discharge head as a droplet. For example, the method is disclosed in JP-A-11-274671 and JP-A-2000-216330. In the inkjet method, a liquid material (functional liquid) for a pattern is directly patterned on a substrate, and then the patterned material is subjected to heating or is irradiated by laser so as to form a desired pattern. Accordingly, in the method, no photolithography is required, processes can be drastically simplified, and the amount of consumed raw material can be reduced since the row material can be directly applied on a patterning position.

Recently, circuits included in devices have been highly densified. This trend requires, for example, wiring lines to be further reduced in width. However, in the pattern forming method using the droplet discharge method described above, it is difficult to stably form a fine pattern since a discharged droplet spreads on a substrate after landing on the substrate. Particularly, when the pattern functions as a conductive film, spreading of the droplet causes a liquid pool (bulge), which may cause a failure such as wire breakage or short. As an alternative, a technique is proposed in JP-A-2005-12181, which employs a bank structure including a region for forming a wide width wiring line, and a region for forming a fine wiring line connected to the region for forming the wide width wiring line. In the technique, a functional liquid is discharged to the region for forming a wide width wiring line, so that the functional liquid flows into the region for forming a fine wiring line by a capillary phenomenon, thereby a fine wiring pattern is formed.

However, the above related art has the following setbacks.

The functional liquid hardly flows into the region for forming a fine wiring line evenly, possibly resulting in an uneven film thickness in the region.

Specifically, in the region for forming a fine wiring line, the film thickness in the vicinity of an area that connects the region for forming a wide width wiring line is larger than that at the end part thereof. This is because pressure (liquid pressure) from the functional liquid is easily transferred to the area, but hardly transferred to the end part. Particularly, the difference in film thickness tends to be larger when a plurality of droplets of the functional liquid is coated and flowed to form wiring lines.

When the related art is applied to form a gate electrode, the following problems arise. One is that stable transistor characteristics are hardly achieved since the characteristic of a TFT element formed above the gate electrode depends on the flatness of a gate insulation film, and the flatness of the gate insulation film is influenced by the flatness of the gate electrode. Another one is that the characteristic of the TFT element could not be achieved since an insulation breakdown is easily induced if the gate electrode has large unevenness or low flatness when the gate insulation film is formed over a bank and the gate electrode.

### SUMMARY

An advantage of the invention is to provide a method for forming a metal wiring line that can perform a desired characteristic with lowering of flatness suppressed, a method for manufacturing an active matrix substrate, a device, an electro-optical device, and an electronic apparatus.

Aspects of the invention will be described below.

A method for forming a metal wiring line according to a first aspect of the invention includes: (a) forming a bank including a first opening corresponding to a first film pattern and a second opening corresponding to a second film pattern that is coupled to the first film pattern and has a width narrower than a width of the first film pattern; (b) disposing a droplet of a functional liquid in the first opening so as to dispose the functional liquid in the second opening by an autonomous flow of the functional liquid; (c) hardening the functional liquid disposed in the first opening and the second opening; and (d) forming the first film pattern and the second film pattern by alternately repeating step (b) and step (c) at least one time. Here, step (b) is referred to as a step A while step (c) is referred to as a step B.

Since one droplet of the functional liquid is hardened each coating of it, an uneven coverage (film thickness difference) between the first and second film patterns can be lessened compared to a case where a plurality of droplets are coated at one time, making the film thickness difference larger due to large pressure applied from the functional liquid in the first opening to that in the second opening. Therefore, repeating the hardening of one droplet each coating of it at a plurality of times allows a plurality of films having less unevenness to be layered to form a metal wiring line with excellent flatness.

It is preferable that the bank include a first bank layer having lyophilicity with respect to the functional liquid and a second bank layer having lyophobicity with respect to the functional liquid, the second bank layer being layered on the first bank layer.

As a result, even if the droplet of the functional liquid is landed on the second bank layer or the upper part of the bank, when the functional liquid is coated, the functional liquid can be repelled and guided to a wiring line forming region. In addition, the functional liquid can favorably wet with respect to the first bank layer, wetting and spreading along the first bank layer since the first bank layer has lyophilicity.

It is preferable that a volume of the droplet disposed in the first opening at one time in step (b) satisfy that a liquid level of the first opening is equal to or lower than a liquid level of the second opening when the functional liquid flows in the second opening.

As a result, the second film pattern with flatness required can easily be formed.

A device according to a second aspect of the invention includes: a substrate; a bank formed on the substrate; a wiring line forming region partitioned by the bank; a metal wiring line that is formed by coating a droplet of a functional liquid in the wiring line forming region and hardening a coated functional liquid; and an insulation film that covers the metal wiring line and the bank. The bank includes an upper surface, a curved surface and a side surface facing the wiring line forming region. The curved surface is formed between the upper surface and the side surface and makes an angle with respect to a surface of the metal wiring line, the angle being set based on an insulation characteristic of the insulation film.

The device can prevent an insulation breakdown from being induced by an electric field concentration due to an edge effect of the gate electrode when a large load is applied to the insulation film that covers the bank and the metal wiring line.

It is preferable that the side surface be tilted at 70 degrees or less with respect to the surface of the substrate and the curved surface make an angle of 45 degrees or less with respect to the surface of the metal wiring line in order to relax a stress concentration produced in the insulation film.

It is preferable that the metal wiring line be formed by alternately repeating coating and hardening the functional liquid at least one time.

The flatness of the metal wiring line can be improved by hardening one droplet of the functional liquid each coating of it compared to a case where a plurality of droplets is coated at one time. Therefore, repeating the hardening of the droplet each coating of it at a plurality of times allows a plurality of films having improved flatness to be layered to achieve a metal wiring line with excellent flatness.

It is preferable that the bank include a first bank layer having lyophilicity with respect to the functional liquid and a second bank layer having lyophobicity with respect to the functional liquid, the second bank layer being layered on the first bank layer.

As a result, even if the droplet of the functional liquid is landed on the second bank layer or the upper part of the bank, when the functional liquid is coated, the functional liquid can be repelled and guided to the wiring forming region. In addition, the functional liquid can favorably wet with respect to the first bank layer, wetting and spreading along the first bank layer since the first bank layer has lyophilicity.

An electro-optical device according to a third aspect of the invention includes the device according to the second aspect of the invention.

An electronic apparatus according to a fourth aspect of the invention includes the electro-optical device according to the third aspect of the invention.

As a result, an electro-optical device and an electronic apparatus having a desired characteristic can be achieved without inducing an insulation breakdown since the electro-optical device and the apparatus are provided with the device of the second aspect, enabling the insulation film covering the metal wiring line to be disposed with high flatness.

A method for manufacturing an active matrix substrate according to a fifth aspect of the invention includes: (a) forming a gate wiring line on a substrate; (b) forming a gate insulation film on the gate wiring line; (c) forming a semiconductor layer on the gate insulation film; (d) forming a source electrode and a drain electrode on the gate insulation film; (e) disposing an insulation material on the source electrode and the drain electrode; and (f) forming a pixel electrode on the insulation material. The method for forming a metal wiring line according to the first aspect of the invention may be used in at least one of steps (a), (d), and (f).

A method for manufacturing an active matrix substrate according to a sixth aspect of the invention includes: (g) forming a source electrode and a drain electrode on a substrate; (h) forming a semiconductor layer on the source electrode and the drain electrode; (i) forming a gate electrode on the semiconductor layer with a gate insulation film interposed between the gate electrode and the semiconductor layer; and (j) forming a pixel electrode so as to be coupled to the drain electrode. The method for forming a metal wiring line according to the first aspect of the invention may be used in at least one of steps (g), (i), and (j).

A method for manufacturing an active matrix substrate according to a seventh aspect of the invention includes: (k) forming a semiconductor layer on a substrate; (l) forming a gate electrode on the semiconductor layer with a gate insulation film interposed between the gate electrode and the semiconductor layer; (m) forming a source electrode so as to be coupled to a source region of the semiconductor layer through a first contact hole formed in the gate insulation film, and a drain electrode so as to be coupled to a drain region of the semiconductor layer through a second contact hole formed in the gate insulation film; and (n) forming a pixel electrode so as to be coupled to the drain electrode. The method for forming a metal wiring line according to the first aspect of the invention may be used in at least one of steps (l), (m), and (n).

The methods can provide a high quality active matrix substrate that performs desired TFT characteristics with the metal wiring line having high flatness since the electrode is formed by the method for forming a metal wiring line of the first aspect.

### BRIEF DESCRIPTION OF THE DRAWINGS

The invention will be described with reference to the accompanying drawings, wherein like numbers reference like elements.

FIG. 1 is a perspective view illustrating a schematic structure of a droplet discharge device.

FIG. 2 is a view describing a discharge principle of a liquid by a piezoelectric method.

FIG. 3A is a plan view illustrating a bank structure

FIG. 3B is a sectional view of FIG. 3A.

FIGS. 4A through 4D are sectional views illustrating steps to form the bank structure.

FIGS. 5A through 5C are sectional views describing steps to form a wiring pattern.

FIGS. 6A through 6C are sectional views describing steps to form a wiring pattern.

FIGS. 7A through 7D are sectional views describing steps to form a wiring pattern.

FIGS. 8A and 8B are schematic views illustrating surface profiles of silver layers.

FIG. 9 is a plan view illustrating a pixel serving as a display area.

FIGS. 10A through 10E are sectional views illustrating steps to form a pixel.

FIG. 11 is a plan view illustrating a liquid crystal display viewed from a counter substrate.

FIG. 12 is a sectional view of the liquid crystal display taken along the line H-H′ in FIG. 11.

FIG. 13 is an equivalent circuit view of the liquid crystal display.

FIG. 14 is a partially enlarged sectional view of an organic EL device.

FIG. 15 shows an example of an electronic apparatus of the invention.

FIG. 16 is a sectional view schematically illustrating an example of an active matrix substrate.

FIG. 17 is a sectional view schematically illustrating another example of the active matrix substrate.

### DESCRIPTION OF EXEMPLARY EMBODIMENTS

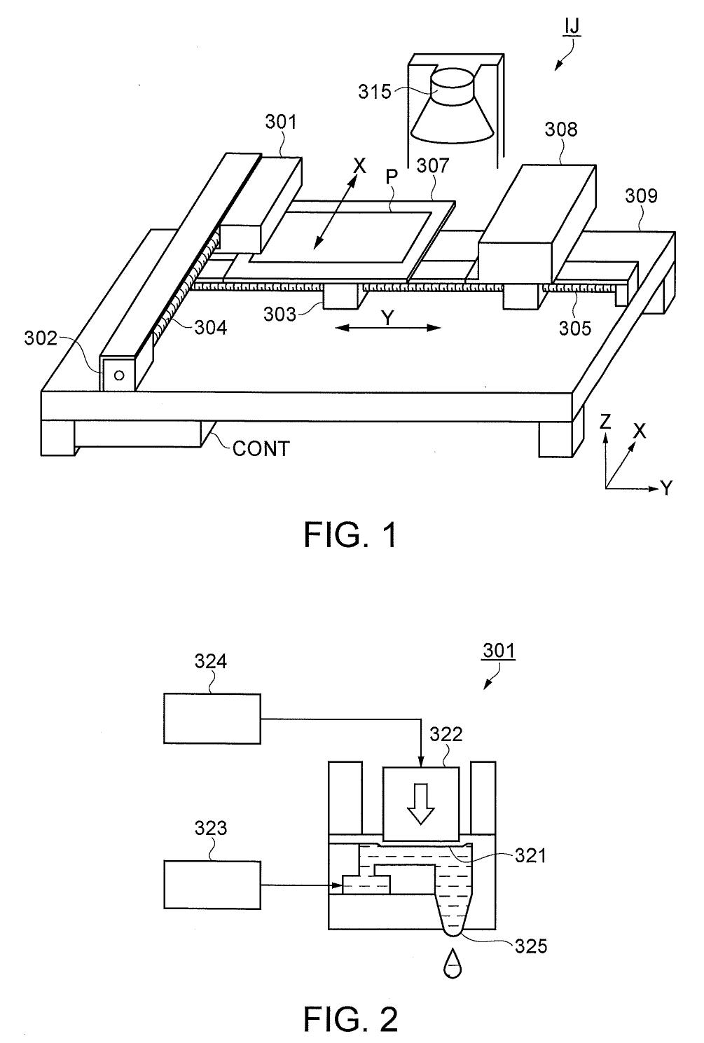

Embodiments of a method for forming a metal wiring line, a method for manufacturing an active matrix substrate, a device, an electro-optical device, and an electronic apparatus according to the invention will be described below with reference to FIGS. 1 through 17.

Note that scales of members in the drawings referred to herein are adequately changed so that they are visible.

Droplet Discharge Device

First, a droplet discharge device, which is used to form a film pattern in a method for forming a metal wiring line according to a first embodiment of the invention, will be described with reference to FIG. 1.

FIG. 1 is a perspective view illustrating a schematic structure of a droplet discharge device (inkjet device) IJ that disposes a functional liquid on a substrate by a droplet discharge method as an example of devices used for the method for forming a film pattern in the first embodiment.

The droplet discharge device IJ includes a droplet discharge head 301, an X-axis direction drive axis 304, a Y-axis direction guide axis 305, a controller CONT, a stage 307, a cleaning mechanism 308, a base 309, and a heater 315.

The stage 307, which supports a substrate P to which ink (a liquid material) is provided by the droplet discharge device IJ, includes a fixing mechanism (not shown) for fixing the substrate P to a reference position. In the embodiment, the stage 307 supports a substrate 18, which will be described later.

The droplet discharge head 301 is a multi-nozzle type droplet discharge head including a plurality of discharge nozzles. The longitudinal direction of the head 301 coincides with the X-axis direction. The plurality of discharge nozzles is disposed on a lower surface of the droplet discharge head 301 in the X-axis direction by a constant interval. The ink (functional liquid) containing conductive particles is discharged from the discharge nozzles included in the droplet discharge head 301 to the substrate P supported by the stage 307.

The X-axis direction drive axis 304 is connected to an X-axis direction drive motor 302. The X-axis direction drive motor 302 is a stepping motor, for example, and rotates the X-axis direction drive axis 304 when the controller CONT supplies the motor 302 with a driving signal for X-axis direction. The X-axis direction drive axis 304 rotates so as to move the droplet discharge head 301 in the X-axis direction.

The Y-axis direction guide axis 305 is fixed so as not to move with respect to the base 309. The stage 307 is equipped with a Y-axis direction drive motor 303. The Y-axis direction drive motor 303 is a stepping motor, for example, and moves the stage 307 in the Y-axis direction when the controller CONT supplies the motor 303 with a driving signal for Y-axis direction.

The controller CONT supplies the droplet discharge head 301 with a voltage for controlling a droplet discharge. The controller CONT also supplies the X-axis direction drive motor 302 with a drive pulse signal for controlling the movement of the droplet discharge head 301 in the X-axis direction, as well as the Y-axis direction drive motor 303 with a drive pulse signal for controlling the movement of the stage 307 in the Y-axis direction.

The cleaning mechanism 308 cleans the droplet discharge head 301. The cleaning mechanism 308 is equipped with a Y-axis direction drive motor (not shown). By driving the Y-axis direction drive motor, the cleaning mechanism 308 is moved along the Y-axis direction guide axis 305. The controller CONT also controls the movement of the cleaning mechanism 308.

The heater 315, which is means to subject the substrate P under heat treatment by a lump annealing in this case, evaporates and dries solvents contained in a liquid material applied on the substrate P. The controller CONT also controls turning on and off of the heater 315.

The droplet discharge device IJ discharges droplets to the substrate P while relatively scanning the droplet discharge head 301 and the stage 307 supporting the substrate P. In the following description, the Y-axis direction is referred to as a scan direction and the X-axis direction perpendicular to the Y-axis direction is referred to as a non-scan direction. Therefore, the discharge nozzles of the droplet discharge head 301 are disposed at a constant interval in the X-axis direction, which is the non-scan direction. While the droplet discharge head 301 is disposed at right angle to the moving direction of the substrate P in FIG. 1, the angle of the droplet discharge head 301 may be adjusted so that the head 301 intersects the moving direction of the substrate P. Accordingly, a pitch between the nozzles can be adjusted by adjusting the angle of the droplet discharge head 301. Also, a distance between the substrate P and the surface of the nozzles may be arbitrarily adjusted.

FIG. 2 is a diagram for explaining a discharge principal of a liquid material by a piezoelectric method.

In FIG. 2, a piezo element 322 is disposed adjacent to a liquid chamber 312 storing a liquid material (ink for a wiring pattern or functional liquid). To the liquid chamber 312, a liquid material is supplied through a liquid material supply system 323 including a material tank that stores the liquid material.

The piezo element 322 is connected to a driving circuit 324. A voltage is applied to the piezo element 322 through the driving circuit 324 so as to deform the piezo element 322, thereby the liquid chamber 312 is deformed to discharge the liquid material from a nozzle 325. In this case, a strain amount of the piezo element 322 is controlled by changing a value of applied voltage. In addition, a strain velocity of the piezo element 322 is controlled by changing a frequency of applied voltage.

Here, various techniques, which are known as a principle to discharge a droplet in known art, can be applied in addition to the piezo method in which ink is discharged by using the piezo element, which is a piezoelectric element described above. The techniques include a bubble method in which a liquid material is discharged by bubbles generated by heating the liquid material, and the like. Among these, the piezoelectric method has an advantage of not giving influence to a composition of a liquid material or the like because no heat is applied to the liquid material.

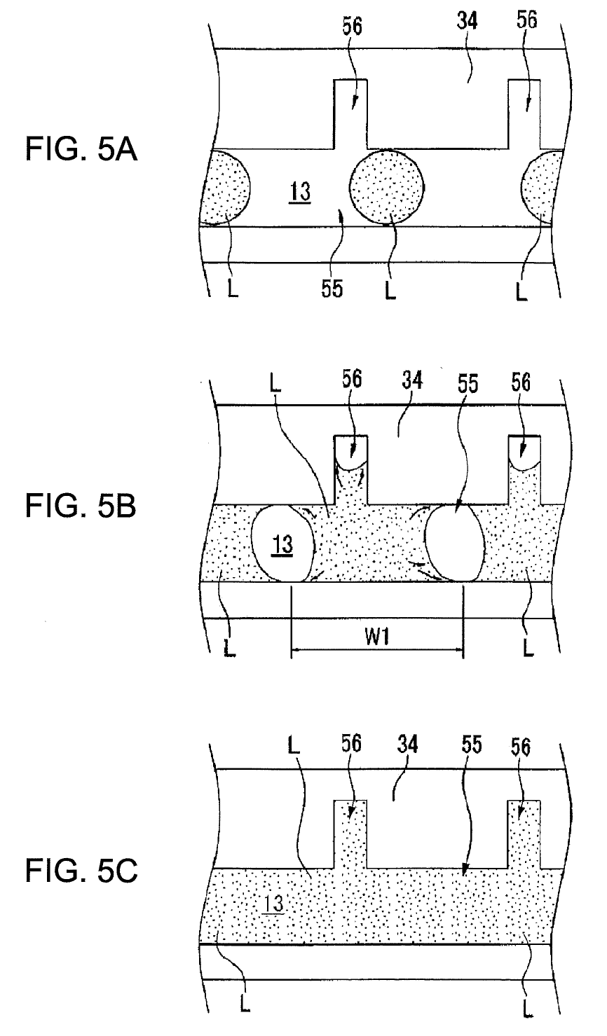

Here, a functional liquid L (refer to FIG. 5) includes a dispersion liquid in which conductive particles, organic silver compounds, or nanoparticles of silver oxide are dispersed in a dispersion medium.

As the conductive fine particles, for example, metal fine particles including: any of Au, Ag, Cu, Pd, Mn, Cr, Co, In, Sn, ZnBi, and Ni; their oxides, alloys, intermetallics, organic salts, and organometallic compounds; and fine particles of a conductive polymer or a super-conductive material or the like are employed.

These conductive fine particles may be used by coating their surfaces with an organic matter or the like to improve their dispersibility.

The diameter of the conductive fine particle is preferably within the range from 1 nm to 0.1 μm. Particles having a diameter larger than 0.1 μm may cause clogging of the discharge nozzle included in the droplet discharge head, which will be described, while particles having a diameter smaller than 1 nm may make the volume ratio of a coated material to the particles so large that the ratio of an organic matter in the resulting film becomes excessive.

Here, any dispersion medium can be used as long as it is capable of dispersing the above conductive fine particles and does not cause an aggregation. Examples of the medium can include: water; alcohols such as methanol, ethanol, propanol, and butanol; hydrocarbon compounds such as n-heptane, n-octane, decane, dodecane, tetradecane, toluene, xylene, cymene, durene, indene, dipentene, tetrahydronaphthalene, decahydronaphthalene, and cyclohexylbenzene; ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis(2-methoxyethyl) ether, and p-dioxane; and polar compounds such as propylene carbonate, gamma-butyrolactone, N-methyl-2-pyrrolidone, dimethylformamide, dimethyl sulfoxide, and cyclohexanone. Water, the alcohols, the carbon hydride series compounds, and the ether series compounds are preferable for the dispersion medium, water and the carbon hydride series compounds are much preferred from the following points of view: a dispersion of the fine particles, stability of a dispersion liquid, and an ease of the application for the droplet discharging method (inkjet method).

The surface tension of the dispersion liquid of the conductive particles is preferably within the range from 0.02 N/m to 0.07 N/m. If the surface tension is below 0.02 N/m when the liquid is discharged by using the droplet discharge method, the wettability of the ink composition with respect to a surface of the discharge nozzle is increased, easily causing a flight curve, while if the surface tension exceeds 0.07 N/m, a meniscus shape at the tip of the nozzle is unstable, rendering the control of the discharge amount and discharge timing problematic. To adjust the surface tension, a fluorine-, silicone- or nonionic-based surface tension adjuster, for example, may be added in a small amount to the dispersion liquid in a range not largely lowering a contact angle with respect to a substrate. The nonionic surface tension adjuster enhances the wettability of a liquid with respect to a substrate, improves leveling property of a film, and serves to prevent minute concavities and convexity of the film from being generated. The surface tension adjuster may include, as necessary, organic compounds, such as alcohol, ether, ester, and ketone.

The viscosity of the dispersion liquid is preferably within the range from 1 mPa·s to 50 mPa·s. When a liquid material is discharged as a droplet by using a droplet discharge method, ink having viscosity lower than 1 mPa·s may contaminate the periphery of the nozzle due to ink leakage. Ink having viscosity higher than 50 mPa·s may possibly cause nozzle clogging, making it difficult to discharge droplets smoothly.

Bank Structure

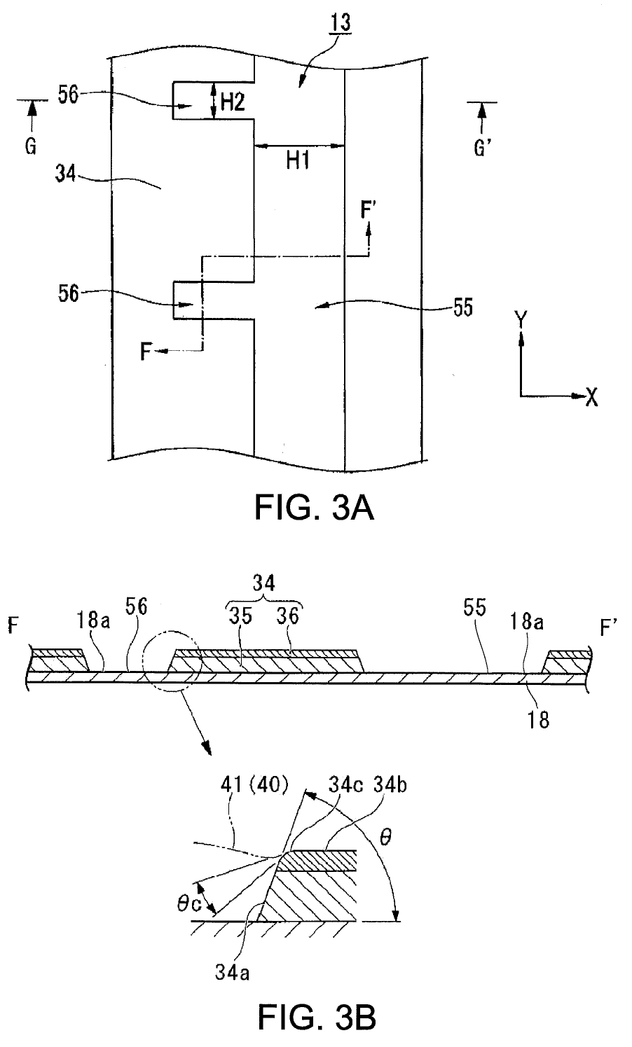

Next, a bank structure, which controls the position of a functional liquid (ink) on a substrate in the embodiment, will be described with reference to FIGS. 3A and 3B.

FIG. 3A is a plan view illustrating a schematic structure of the bank structure. FIG. 3B is a sectional view illustrating the bank structure taken along the line F-F′ in FIG. 3A.

As shown in FIGS. 3A and 3B, the bank structure of the embodiment is structured so that a bank 34 is formed on a substrate 18. A region partitioned by the bank 34 is a pattern forming region (wiring line forming region) 13, to which a functional liquid is disposed. The pattern forming region 13 of the embodiment is provided on the substrate 18, to which a gate wiring line and a gate electrode are formed so as to structure a TFT, which will be described later.

The pattern forming region 13 includes a first pattern forming region (a first opening) 55 and a second pattern forming region (a second opening) 56 connected to the region 55, both of which have a groove shape in section. The region 55 corresponds to a gate wiring line (a first film pattern), while the region 56 corresponds to a gate electrode (a second film pattern). Here, the term “correspond” means that a functional liquid disposed in the region 55 or the region 56 turns into a gate wiring line or a gate electrode respectively by performing a hardening treatment or the like.

Specifically, as shown in FIG. 3A, the region 55 is formed so as to extend in the Y-axis direction. The region 56 is formed so as to be about perpendicular to the region 55 (in the X-axis direction in FIG. 3A), and be continuously connected to the region 55. The bank 34, which forms the regions 55 and 56, includes a tilted surface (side surface) 34a, which tilts at an angle θ with respect to the surface of the substrate 18, un upper surface 34b, and a curved surface 34c formed between the upper surface 34b and the tilted surface 34a as shown in FIG. 3B, which is a partially enlarged view. The tilting angle of the tilted surface 34a and the curvature factor of the curved surface 34c are determined based on insulation characteristics of an insulation film that covers the bank 34, the gate electrode 41 and the gate wiring line 40. Details will be described later.

In addition, the width of the region 55 is wider than that of the region 56. In the embodiment, the width of the region 55 is formed so that it is nearly equal to, or slightly larger than a diameter of a flying functional liquid droplet discharged from the droplet discharge device IJ. Employing such bank structure allows a functional liquid discharged in the region 55 to flow into the region 56, which is a fine pattern, by utilizing a capillary phenomenon.

The width of the region 55 is expressed by the length between the edges of the upper surface 34b in the region 55 in the direction perpendicular to the direction in which the region 55 extends (in the Y direction). Likewise, the width of the region 56 is expressed by the length between the edges of the upper surface 34b in the region 56 in the direction perpendicular to the direction in which the region 56 extends (in the X direction). That is, as shown in FIG. 3A, the width of the region 55 is expressed by a length H1, while the width of the region 56 is expressed by a length H2.

FIG. 3B shows the sectional view (F-F′ section) of the bank structure. Specifically, the bank 34 having a multilayered structure is disposed on the substrate 18. In the embodiment, the bank 34 has a two-layer structure of a first bank layer 35 and a second bank layer 36, which are layered in this order from the substrate 18. In addition, the second bank layer 36, which is the upper layer in the bank 34, has higher lyophobicity than the first bank layer 35, while the first bank layer 35, which is the lower layer in the bank 34, has relatively higher lyophilicity than the second bank layer 36. Accordingly, even if a functional liquid is landed on the upper surface of the bank 34, the functional liquid flows into the regions 55 and 56 (mainly into the region 55) since the upper surface has lyophobicity. As a result, the functional liquid adequately flows in the regions 55 and 56.

In the embodiment, the first bank layer 35 has a contact angle of less than 50 degrees with respect to a functional liquid on the tilted surface 34a, which facing the regions 55 and 56. In contrast, the second layer 36, which is formed by a bank forming material that includes a fluorine bond at a side chain therein or a material that includes a silane containing fluorine or surfactant, has a contact angle larger than that of the first bank layer 35 with respect to a functional liquid. The contact angle with respect to a functional liquid at the surface of the second bank layer 36 is preferably 50 degrees or more. In addition, the bottom face of the pattern forming region 13 (a surface 18a of the substrate 18) to which a droplet of a functional liquid is provided has a contact angle equal or less than that of the first bank layer 35 with respect to a functional liquid.

In the embodiment, the contact angles of the first bank layer 35 and the bottom face are preferably adjusted so that the sum of the contact angle on the side surface of the first bank layer 35 and the contact angle on the bottom face of the region 13 becomes small compared to the contact angle of the second bank layer 36. The resulting structure makes it possible to achieve an effect to further improve wettability of the functional liquid L.

Method for Forming a Film Pattern

Next, a method for forming the bank structure in the embodiment, and a method for forming a gate wiring line as a film pattern on the pattern forming region 13, which is partitioned by the bank structure, will be described.

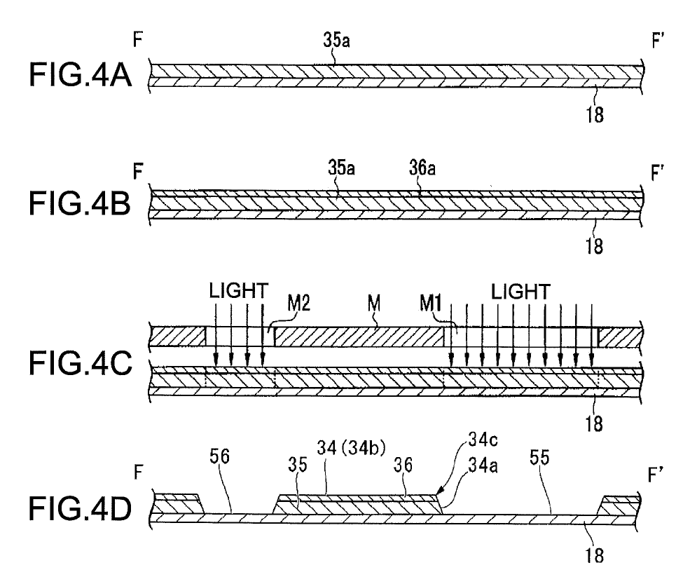

FIGS. 4A through 4D are sectional views sequentially illustrating the forming process of the bank structure. FIGS. 4A through 4D are diagrams illustrating the forming process of the pattern forming region 13 including the first pattern forming region 55 and the second pattern forming region 56 based on the sectional view taken along the line F-F′ of FIG. 3A. FIGS. 5A through 5C are sectional views describing the forming process of a film pattern (gate wiring line) by disposing a functional liquid to the bank structure formed in the manufacturing process shown in FIGS. 4A through 4D.

Bank Material Coating Step

First, a first bank forming material is coated on the entire surface of the substrate 18 by spin coating so as to form a pre-first bank layer 35a (drying condition: at 80° C. and for 60 seconds) as shown in FIG. 4A. Then, a second bank forming material is coated by spray coating on the first bank forming material so as to form a pre-second bank layer 36a (drying condition; at 80° C. and for 60 seconds) as shown in FIG. 4B. In this case, various methods such as spray coating, roll coating, die coating, dip coating, and an inkjet method can be applied as the coating method of the bank forming materials.

As the substrate 18, materials such as glass, quartz glass, a Si wafer, a plastic film, a metal plate can be used. On the surface of the substrate 18, an underlayer such as a semiconductor film, a metal film, a dielectric film and an organic film may be formed.

As the first bank forming material, a material is used that has a relatively high affinity with respect to a functional liquid. That is, a material (polymer) can be used that has a siloxane bond as a main chain, and a side chain that includes at least one type chosen from the following list: —H, —OH, —(CH₂CH₂O)nH, —COOH, —COOK, —COONa, —CONH₂, —SO₃H, —SO₃Na, —SO₃K, —OSO₃H, —OSO₃Na, —OSO₃K, —PO₃H₂, —PO₃Na₂, —PO₃K₂, —NO₂, —NH₂, —NH₃Cl (ammonium salt), —NH₃Br (ammonium salt), ≡HNCl (pyridinium salt), and ≡NHBr (pyridium salt).

In addition to the materials, as the first bank forming material, a material also can be used that has a siloxane bond as a main chain, and a side chain a part of which includes an alkyl group, an alkenyl group, or an aryl group.

In the embodiment, the contact angle with respect to a functional liquid at the side wall of the first bank layer 35 is adjusted less than 50 degrees by using the above first bank forming material. By adjusting the contact angle less than 50 degrees, the functional liquid L can wet and flow in the pattern forming region 13 so as to extend along the side wall of the first bank layer 35, thereby a film pattern can be formed rapidly and stably. Details will be described later.

In contrast, as the second bank forming material, a material is used that can form a bank that has a contact angle larger than that of the first bank layer 35 with respect to a functional liquid, and a relatively low affinity with respect to the functional liquid.

That is, a material that has a siloxane bond as a main chain and a fluorine bond as a side chain thereof, or a material that has a siloxane bond as a main chain and includes a silane compound containing fluorine or a surfactant containing fluorine, is used as the second bank forming material.

As the material that has a siloxane bond as a main chain and a fluorine bond as a side chain thereof, materials can be exemplified that include one or more type selected from F group, —CF₃ group, —CF₂-chain, —CF₂CF₃, —(CF₂)ₙCF₃, and —CF₂CFCl— as the side chain.

As silane compounds containing fluorine (silane compounds having lyophobicity), alkylsilane compounds containing fluorine can be exemplified. That is, the compounds have a structure in which perfluoroalkyl structure expressed as CₙF₂ₙ₊₁ and silicon are bonded, and compounds expressed by the following general formula (1) can be exemplified. In formula (1), n is an integer from 1 to 18, m is an integer from 2 to 6, X¹ and X² represent —OR², —R², and —CL, R² included in X¹ and X² represents an alkyl group having the number of carbons of 1 to 4, and a is an integer from 1 to 3.

R² is a functional group to form an alkoxy group and chlorine radical, an Si—O—Si bond, and the like in X¹, and hydrolyzed with water to be removed as alcohol or acid. Examples of the alkoxy group includes a methoxy group, an ethoxy group, an n-propoxy group, an isopropoxy group, an n-butoxy group, an isobutoxy group, a sec-butoxy group, and a tert-butoxy group.

The number of carbons of R² is preferably within the range from 2 to 4 from the point of view that alcohol to be removed has a relatively small molecular amount, and can be easily removed, and density of formed film can be prevented from being lowered.

By using the alkylsilane compound containing fluorine, each compound is oriented so that the fluoroalkyl group is placed on the surface of a film to form a self-assembled film. As a result, lyophobicity can be evenly given to the surface or the film.

CₙF₂ₙ₊₁(CH₂)ₘSiX¹ₐX²₍₃₋ₐ₎ General formula (1)

Specifically, the following compounds can be exemplified: CF₃—CH₂CH₂—Si(OCH₃)₃, CF₃(CF₂)₃—CH₂CH₂—Si(OCH₃)₃, CF₃(CF₂)₅—CH₂CH₂—Si(OCH₃)₃, CF₃(CF₂)₅—CH₂CH₂—Si(OC₂H₅)₃, CF₃(CF₂)₇—CH₂CH₂—Si(OCH₃)₃, CF₃(CF₂)₁₁—CH₂CH₂—Si(OC₂H₅)₃, CF₃(CF₂)₃—CH₂CH₂—Si(CH₃)(OCH₃)₂, CF₃(CF₂)₇—CH₂CH₂—Si(CH₃)(OCH₃)₂, CF₃(CF₂)₈—CH₂CH₂—Si(CH₃)(OC₂H₅)₂, and CF₃(CF₂)₈—CH₂CH₂—Si(C₂H₅)(OC₂H₅)₂.

Compounds having a structure in which R¹ is expressed by a perfluoroalkylether structure of CₙF₂ₙ₊₁O(CₚF₂ₚO)ᵣ is also exemplified. As specific examples, compounds expressed by the following general formula (2) can be exemplified.

CₚF₂ₚ₊₁O(CₚF₂ₚO)ᵣ(CH₂)ₘSiX¹ₐX²₍₃₋ₐ₎ General formula (2)

Where m is an integer from 2 to 6, p is an integer from 1 to 4, r is an integer from 1 to 10, and X¹, X², and a present the same meanings as described above. Specifically, the following compounds can be exemplified: CF₃O(CF₂O)₆—CH₂CH₂—Si(OC₂H₅)₃, CF₃O(C₃F₆O)₄—CH₂CH₂—Si(OCH₃)₃, CF₃O(C₃F₆O)₂(CF₂O)₃—CH₂CH₂—Si(OCH₃)₃, CF₃O(C₃F₆O)₈—CH₂CH₂—Si(OCH₃)₃, CF₃O(C₄F₉O)₅—CH₂CH₂—Si(OCH₃)₃, CF₃O(C₄F₉O)₅—CH₂CH₂—Si(CH₃)(OC₂H₅)₂, and CF₃O(C₃F₆O)₄—CH₂CH₂—Si(C₂H₅)(OCH₃)₂.

Silane compounds having the fluoroalkyl group or perfluoroalkylether structure are collectively named as “FAS.” These compounds can be used singly or in combination. The use of FAS allows adhesiveness with a substrate and good lyophobicity to be achieved.

As surfactants, ones expressed by general formula of R¹Y¹ can be used. In the formula, R¹ is an organic group having hydrophobicity, and Y¹ is a polar radical having hydrophilicity such as —OH, —(CH₂CH₂O)nH, —COOH, —COOA, —CONH₂, —SO₃A, —OSO₃H, —OSO₃A, —PO₃H₂, —PO₃A, —NO₂, —NH₂, —NH₃B (ammonium salt), ≡NHB (pyridium salt), and —NX¹₃B (alkylammonium salt). Here, A represents one or more positive ion, while B represents one or more negative ion. X¹ represents an alkyl group having the number of carbons of 1 to 4 as the same meaning as described above.

The surfactant expressed by the above general formula is an amphipathic compound, in which an organic group R¹ having lipophilicity and a functional group having hydrophilicity are bonded. Y¹ represents a polar radical having hydrophilicity and is a functional group to bond or adsorb to a substrate. The organic group R¹ has lipophilicity and is arranged at a side opposite to a hydrophilic surface so that a lipophilic surface is formed on the hydrophilic surface. In the embodiment, surfactants having a structure in which the organic group R¹ has the perfluoroalkyl structure of CₙF₂ₙ₊₁ is useful since the surfactants are added into the second bank forming material for the purpose of giving lyophobicity to the second bank layer 36. Specifically, the following compounds can be exemplified: F(CF₂CF₂)₁₋₇—CH₂CH₂—N⁺(CH₃)₃Cl⁻, C₈F₁₇SO₂NHC₃H₆—N⁺(CH₃), F(CF₂CF₂)₁₋₇—CH₂CH₂SCH₂CH₂⁻CO₂—Li⁺, C₈F₁₇SO₂N(C₂H₅)—CO₂⁻K⁺, (F(CF₂CF₂)₁₋₇)CH₂CH₂O)_{1,2}PO(O⁻NH₄⁺)_{1,2}, C₁₀F₂₁SO₃⁻NH₄⁺, C₆F₁₃CH₂CH₂SO₃H, C₆F₁₃CH₂CH₂SO₃⁻NH₄⁺, C₈F₁₇SO₂N(C₂H₅)—(CH₂CH₂O)₀₋₂₅H, C₈F₁₇SO₂N(C₂H₅)—(CH₂CH₂O)₀₋₂₅CH₃, and F(CF₂CF₂)₁₋₇—CH₂CH₂O—(CH₂CH₂O)₀₋₂₅H. The surfactants including the fluoroalkyl group can be used singly or in combination.

The second bank layer 36 is also may be structured as a surface treatment layer of the first bank layer 35. In this case, for example, EGC-1700, and EGC-1720 available from Sumitomo 3M Limited can be used as a fluorine-based surfactant to form the second bank layer 36. However, if the thickness of the surface treatment layer exceeds 1 μm, pattern forming failure may likely occur in the development step. The thickness of the surface treatment layer is preferably 500 nm or less, specifically, about from 50 nm to about 100 nm, for example. As a solvent of a surface treatment agent, for example, hydrofluoroether that is hard to dissolve the first bank layer can be used.

Using these materials enables the surface of the second bank layer 36 to have good lyophobicity, holding the functional liquid disposed in the pattern forming region 13 therein. Further, droplets of the functional liquid landed on out of the pattern forming region 13 can flow into the pattern forming region 13 because of lyophobicity of the second bank layer 36. As a result, a film pattern having an accurate planer shape and thickness is formed.

Exposure Step

Next, as shown in FIG. 4C, the pre-bank layers 35a and 36a formed on the substrate 18 are irradiated by light from an exposure device (not shown) through a mask M so as to form the first pattern forming region 55 and 56. In this process, the pre-bank layers 35a and 36a, which are exposed by the irradiation of light, are turned into a state that they can be dissolved and removed in a development process described later. As a result, the bank structure having the pattern forming region 13 described above is formed.

Development Step

After the exposure step, as shown in FIG. 4D, the pre-bank layers 35a and 36a that have been exposed are developed with tetramethylammonium hydroxide (TMAH), for example, so as to selectively remove the exposed part. In the step, the angle θ of the tilted surface 34a, which faces the regions 55 and 56, of the bank 34 is 45 degrees to 70 degrees (preferably 60 degrees or more). If θ is 45 degrees or less, the gate electrode 41 (the gate wiring line 40) increasingly tends to be shaped in convex, and the degree of flexion of a gate insulation film 39, which covers the upper surface of the bank 34 and the gate electrode 41 (the gate wiring line 40), becomes larger. An insulation breakdown is easily induced by an electric field concentration due to an edge effect of the gate electrode 41 (the gate wiring line 40). Therefore, the development conditions are adjusted so that θ is 45 degrees to 70 degrees (preferably, 60 degrees or more). In the development step, since the intersecting part of the upper surface 34b and the tilted surface 34a of the bank 34 forms an edge, which is massively eroded by a developer, whereby the curved surface 34c is formed in an arc-shape. The curved surface 34c is also formed by adjusting development conditions so that the curved surface 34c makes an angle of 45 degrees or less with respect to the liquid level of a functional liquid coated on the regions 55 and 56 from the same reason of the tilting angle of the bank 34.

Then a firing (at 300° C. and for 60 minutes) is carried out. As a result, the bank 34, which defines the pattern forming region 13 including the regions 55 and 56, is formed on the substrate 18 as shown in FIG. 4D. Here, the bank 34 is formed about 0.5 μm in height (the depth of regions 55 and 56).

The bank 34 has a two-layer structure in which the bank layers 35 and 36, each of which has a different affinity with respect to a functional liquid, are layered. The surface of the second bank layer 36 serving as the upper layer has a relatively higher lyophobicity than that of the first bank layer 35 with respect to the functional liquid. In contrast, the inside surface of the first bank layer 35, which faces the pattern forming region 13, has lyophilicity, since the first bank layer 35 is made of a material having lyophilicity, thereby a functional liquid easily spreads.

After the firing step, prior to a succeeding functional liquid disposition step, the substrate 18 on which the bank 34 has been formed may be cleaned by hydrogen fluoride (HF). Fluorine is evaporated from the second bank layer 36 that contains fluorine and may adhere on the bottom (a substrate surface 18a) of the pattern forming region 13 since the firing is carried out at a high temperature of about 300° C. The adherence of fluorine on the bottom of the pattern forming region 13 lowers lyophilicity on the bottom, thereby lowering the wetting and spreading property of the functional liquid L. Therefore, fluorine adheres on the bottom is preferably removed by HF cleaning.

In the embodiment, the functional liquid L can be discharged and disposed in the pattern forming region 13 that has been formed by development without firing the bank 34. In this case, HF cleaning is not needed.

Functional Liquid Disposition Step

Next, a process to form a metal wiring line will be described. In the process, a functional liquid is discharged and disposed in the pattern forming region 13, which is formed by the bank structure achieved in the above-described steps, by using the droplet discharge device IJ. Here, it is difficult to directly dispose the functional liquid L to the second pattern forming region 56 for forming a fine wiring pattern. Therefore, the functional liquid L is disposed to the region 56 by flowing the functional liquid L disposed to the region 55 by a capillary phenomenon described above. The method will be described below.

First, as shown in FIG. 5A, the functional liquid L containing metal fine particles is discharged to the first pattern forming region 55 as a wiring pattern forming material by the droplet discharge device IJ. The functional liquid L disposed to the region 55 by the droplet discharge device IJ flows, wets and spreads in the region 56 from the region 55 by a capillary phenomenon as shown in FIG. 5B. Then, as shown in FIG. 5C, the region 56 is filled with the functional liquid L to form the first film pattern having a wide width and the second film pattern that is connected to the first film pattern and has a narrow width.

Even if the functional liquid L is disposed on the upper surface of the bank 34, the functional liquid L is repelled and flows into the region 55 since the upper surface has lyophobicity.

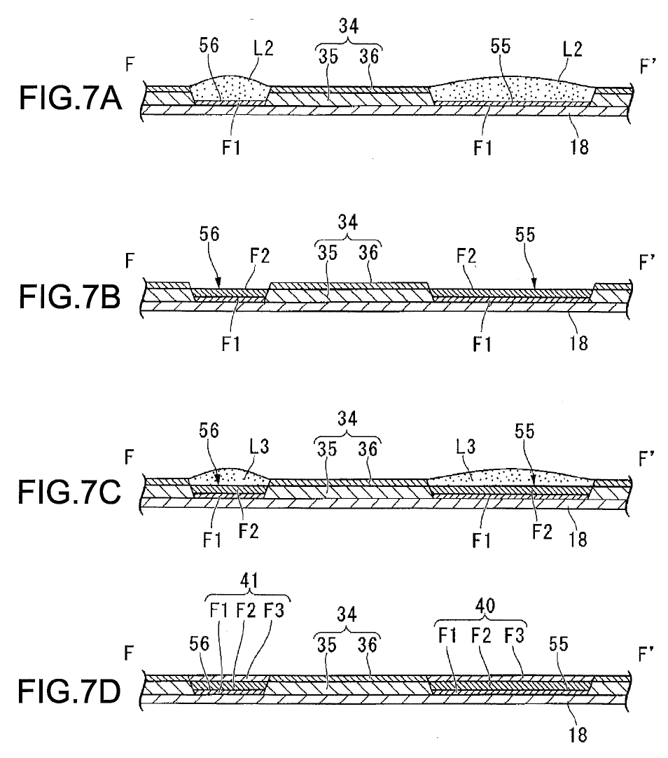

Next, the process to form the gate wiring line (the first film pattern) 40 in the first pattern forming region 55 and the gate electrode (the second film pattern) 41 in the second pattern forming region 56 as shown in FIG. 7D by using the above method for forming a metal wiring line will be described.

In the embodiment, each of the gate wiring line 40 and the gate electrode 41 is formed as a wiring pattern including three layers.

Specifically, each of the gate wiring 40 and the gate electrode 41 in the embodiment is formed with three layers that are a manganese layer (foundation layer) F1, a silver layer (wiring layer) F2, and a nickel layer (protective layer) F3 in this order from the layer F1.

The manganese layer F1 acts as an under layer (intermediate layer) to improve the adherence of the silver layer F2 to the substrate 18. The silver layer F2 is formed and layered on the manganese layer F1 as a conductive layer. The nickel layer F3 acts as a thin film to suppress an electro migration phenomenon or the like of a conductive film made of silver or copper or the like, and is formed so as to cover the silver layer F2.

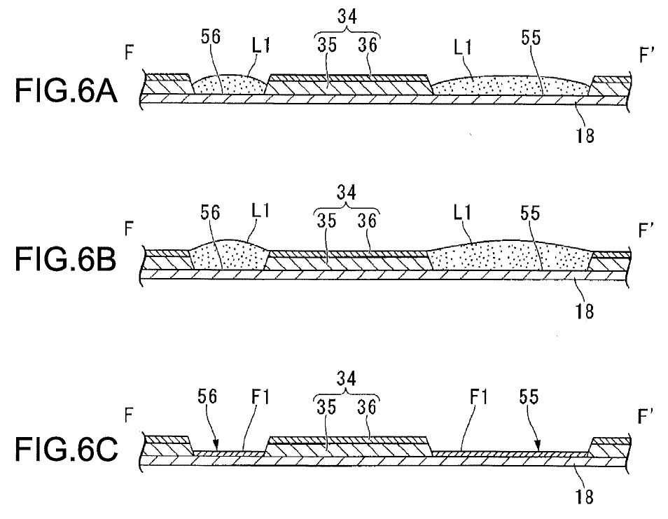

Steps to form each layer will be described below with reference to FIGS. 6A through 7D.

First, a functional liquid L1 that includes manganese (Mn) dispersed as a conductive particle in an organic dispersion medium and forms the manganese layer F1 is discharged on the first pattern forming region 55 with the droplet discharge device IJ. The functional liquid L1 disposed in the region 55 by the droplet discharge device IJ wets and spreads in the region 55 (step A).

The functional liquid L, which is discharged and disposed, adequately flows in the entire area of the pattern forming region 13 since the tilted surface 34a of the first bank layer 35 shows lyophilicity. As shown in FIGS. 6A and 6B, the functional liquid L fills in the region 55 and smoothly flows in the region 56 by a capillary phenomenon (step A).

In this case, the functional liquid L1 of 3.5 ng is coated. Then, the functional liquid L1 (the manganese layer F1) is dried and fired to remove the dispersion medium (organics). The drying and firing treatments secure the electrical contact between conductive fine particles, whereby the functional liquid L1 disposed turns to a conductive film. As the drying treatment, a heating treatment using a typical hot plate, electric furnace, or the like to heat the substrate P may be employed, for example. The drying treatment is mainly to reduce unevenness of film thickness and performed by heating at 120° C. for two minutes. The processing temperature for the firing treatment is determined at an appropriate level, taking into account the boiling point (vapor pressure) of a dispersion medium, dispersibility of fine particles, thermal behavioral properties such as oxidizability of fine particles, the presence and volume of a coating material, and the heat resistance temperature of a base material, or the like. For example, eliminating a coating material made of an organic matter requires firing it at about 220° C. for 30 minutes. As a result, the manganese layer F1 having a thickness of 0.05 μm is formed as shown in FIG. 6C.

Then, in order to form the silver layer F2, a droplet of a functional liquid L2 is disposed in the regions 55 in which the manganese layer F1 has been formed as shown in FIG. 7A. In the functional liquid L2, nanoparticles of silver (Ag) serving as conductive fine particles are dispersed in an organic dispersion medium. To the functional liquid L2, a dispersion stabilizing agent of an amino compound is added other than the nanoparticles of silver, for example. In order to form the silver layer F2 having a thickness of about 0.43 μm, 5 droplets of the functional liquid L2 is disposed in the region 55 to be flowed in the region 56, where one droplet is 7.5 ng. In forming the layer, the drying and firing treatments are carried out each coating of one droplet of the functional liquid L2 rather than coating droplets of the functional liquid at one time (step B).

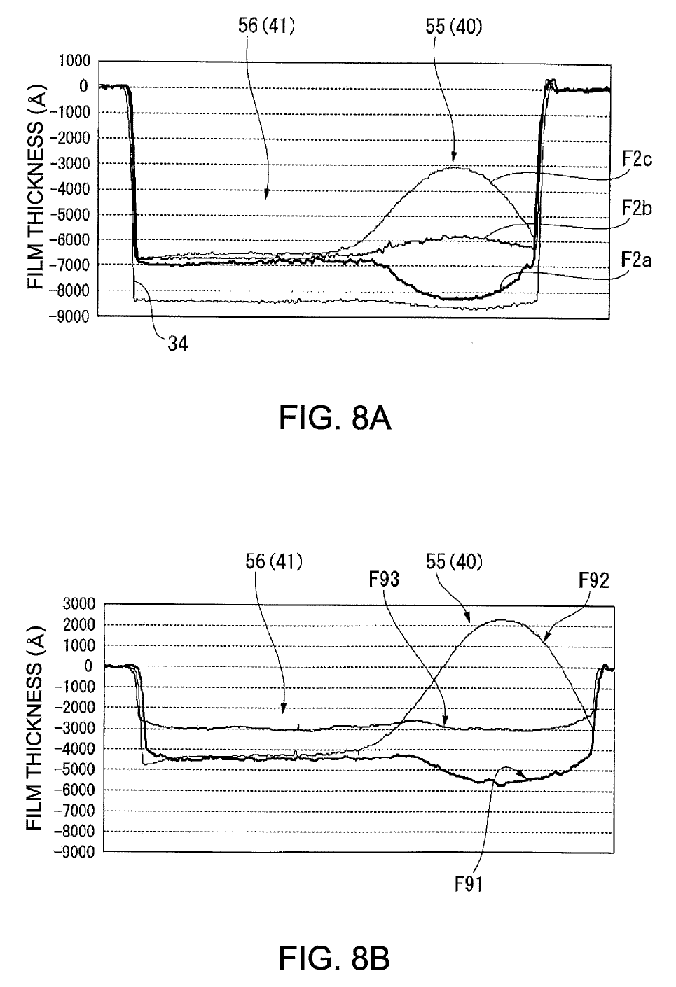

FIG. 8A is a sectional view illustrating the bank structure taken along the line G-G′ in FIG. 3A. In FIG. 8A, surface profiles F2a, F2b, and F2c of the silver layer F2 are shown. The surface profile F2a shows the surface profile of the silver layer F2 that is formed by drying and firing each droplet of the functional liquid L2 discharged and coated at a predetermined position. The surface profile F2b shows the surface profile of the silver layer F2 that is formed by drying and firing 2 droplets discharged and coated at a predetermined position at one time. The surface profile F2c shows the surface profile of the silver layer F2 that is formed by drying and firing 3 droplets discharged and coated at a predetermined position at one time. As shown in FIG. 8A, the thickness of the gate electrode 41 formed by the droplets flowed in the region 56 is roughly unchanged even though the number of droplets coated in the region 55 increases. The functional liquid of increased droplets contributes to increase the thickness of the gate wiring line 40. In other words, increasing the number of droplets of the functional liquid to be coated makes the thickness difference between the gate electrode 41 and the gate wiring line 40 larger.

In contrast, the surface profile F2a is relatively flat, which is the surface profile of the silver layer F2 formed by drying and firing each droplet of the functional liquid coated.

Therefore, when the silver layer F2 is formed by using a plurality of droplets of the functional liquid L2, the silver layer F2 that is flat and composed of each evenly formed silver layer can be achieved by alternately repeating a step, in which the drying and firing treatments are carried out after one droplet is coated, at a plurality of times.

The volume of a droplet discharged in the first opening at one coating is preferably that the liquid level of the first opening is lower than that of the second opening when the discharged droplet flows in the second opening. That is, such volume realizes the state of the liquid level shown by the surface profile F2a in FIG. 8A.

For example, when the gate electrode 41 is formed by coating droplets in the region 55, as shown in FIG. 8B, a surface profile F91 of the silver layer formed by repeating the step, in which the drying and firing treatments are carried out after one droplet is coated, for each droplet of the functional liquid up to 3 droplets. Compared to the surface profile F2c that is the profile of the silver layer formed by drying and firing the 3 droplets at one time after they are coated, the surface profile F91 shows that the thickness of the gate electrode 41 is thicker, and the flatness is smaller than the surface profile F2c. That is, the flatness is improved.

Likewise, surface profiles F92 and F93 are compared as follows: the surface profile F92 of the silver layer formed by drying and firing 6 droplets at one time after they are coated shows that the profile swells in region 55 and the thickness of gate electrode 41 formed in the region 56 does not satisfy the thickness corresponding to the number of droplets; and the surface profile F93 of the silver layer formed by repeating the step, in which the drying and firing treatments are carried out after one droplet is coated, for each droplet of the functional liquid up to 5 droplets shows that the thickness of the gate electrode 41 is thick despite small number of coated droplets, and the silver layer can be formed with less unevenness between the gate electrode 41 and the gate wiring line 40.

In drying and firing each coated droplet of the functional liquid L2 in order to remove the dispersion medium and dispersion stabilizing agent, first, the dispersion medium (organics) is removed (oxidized) by pre-firing it in the atmosphere, and then firing it in a nitrogen gas atmosphere. The pre-firing to oxidize organics is preferably carried out at 130° C. or more, and 230° C. or less. The upper limit (230° C. or less) is necessary to suppress a grain growth of silver, which has a characteristic of its grain growing when heated under a condition including oxygen. In the embodiment, the pre-firing is carried out at about 220° C. for 30 minutes in the atmosphere. The firing is preferably carried out from 230° C. to 350° C., for example. In the embodiment, the firing is carried out at about 300° C. for 30 minutes in a nitrogen gas atmosphere. In the embodiment, grain growth is suppressed since the firing is carried out in a nitrogen gas atmosphere.

After the firing, the silver layer F2 having a thickness of 0.43 μm is formed on the manganese layer F1 as shown in FIG. 7B.

Subsequently, to form the nickel layer F3, a droplet of a functional liquid L3, which is made of an organic dispersion medium including nickel dispersed as a conductive fine particle, is disposed in the region 55 as shown in FIG. 7C. In a similar manner of the functional liquids L1 and L2, the functional liquid L3 fills in the region 55 and smoothly flows in the region 56 by a capillary phenomenon.

After coating 2 droplets, one droplet is 2.5 ng, of the functional liquid, they are dried and fired in order to remove the dispersion medium.

At first, drying is carried out at about 70° C. for 10 minutes in the atmosphere in order to prevent them from uneven drying. Next, pre-firing is carried out at about 220° C. for 30 minutes in the atmosphere in order to remove (oxidize) the dispersion medium (organics) in a same manner of forming the silver layer F2. Then, firing is carried out at about 300° C. for 30 minutes in a nitrogen gas atmosphere in order to suppress growing of silver grains.

Through the drying and firing treatment, the nickel layer F3 having a thickness of 0.02 μm is formed as a protective layer by being layered on the silver layer F2. The gate wiring line 40 is formed in the region 55 while the gate electrode 41 is formed in the region 56.

Here, the curvature factor of the curved surface 34c is set so that an angle θc shown in FIG. 3 B is 45 degrees or less. The θc is an angle that the curved surface 34c makes with respect to each surface of the gate electrode 41 (the nickel layer F3) and the gate wiring line 40 (the nickel layer F3).

Device

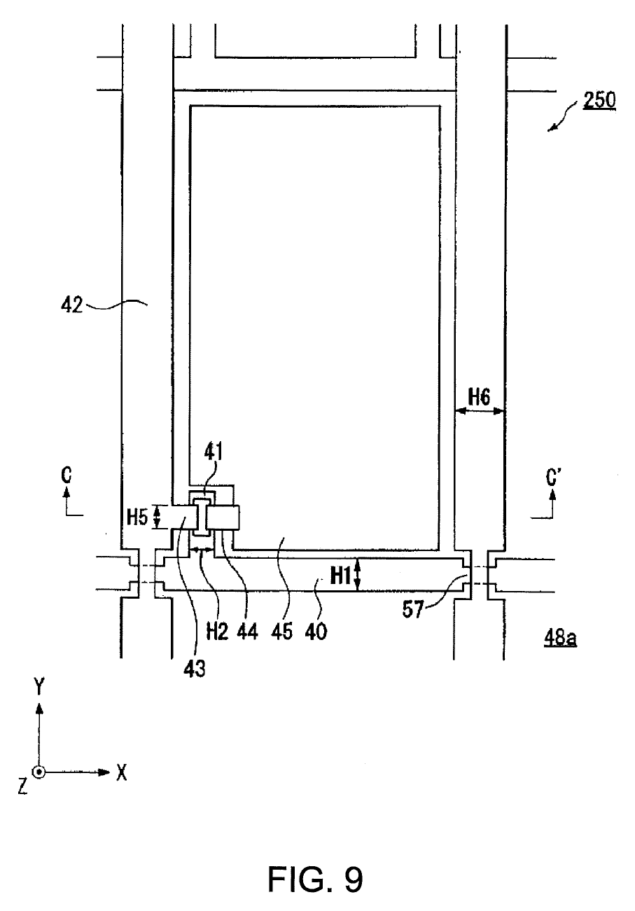

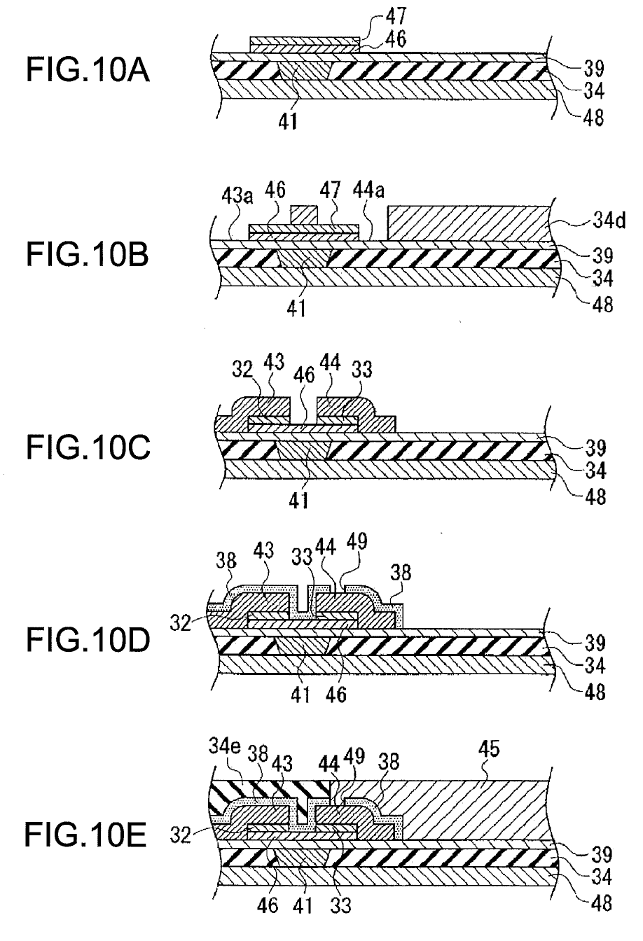

Next, a device according to a second embodiment of the invention will be described. The device has a metal wiring line formed by the method for forming a metal wiring line of the first embodiment. In the embodiment, a pixel (device) having a gate wiring line, and a method for forming the pixel will be described with reference to FIG. 9 and FIGS. 10A through 10E.

In the embodiment, a pixel, which includes a gate electrode, a source electrode, a drain electrode, and the like of a TFT 30 of a bottom gate type, is formed by using the above-described methods for forming a bank structure and a metal wiring line. In the following description, the description of the same process in the film pattern forming process shown in FIGS. 6A and 7D will be omitted. The structural element the same as that in the first embodiment is given the same numeral.

Pixel Structure

First, the structure of a pixel (device) having a metal wiring line formed by the above-described method for forming a film pattern will be described.

FIG. 9 shows a pixel structure 250 of the embodiment.

As shown in FIG. 9, the pixel structure 250 is provided, on a substrate, with a gate wiring line 40 (the first film pattern), a gate electrode 41 (the second film pattern) formed so as to be extended from the gate wiring line 40, a source wiring line 42, a source electrode 43 formed so as to be extended from the source wiring line 42, a drain electrode 44, and a pixel electrode 45 electrically connected to the drain electrode 44. The gate wiring line 40 is formed so as to extend in the X-axis direction, while the source wiring line 42, which intersects the gate wiring line 40, is formed so as to extend in the Y-axis direction. In the vicinity of the intersection of the gate wiring line 40 and the source wiring line 42, a TFT, which is a switching element, is formed. By turning on the TFT, a drive current is supplied to the pixel electrode 45 connected to the TFT.

As shown in FIG. 9, the width H2 of the gate electrode 41 is formed so as to be narrower than the width H1 of the gate wiring line 40. For example, the width H2 of the gate electrode 41 is 10 μm, while the width H1 of the gate wiring line 40 is 20 μm. The gate wiring line 40 and the gate electrode 41 are formed by the method for forming a metal wiring line of the first embodiment.

A width H5 of the source electrode 43 is formed so as to be narrower than a width H6 of the source wiring line 42. For example, the width H5 of the source electrode 43 is 10 μm, while the width H6 of the source wiring line 42 is 20 μm. In the embodiment, a functional liquid flows into the source electrode 43, which is a fine pattern, by a capillary phenomenon by applying the method for forming a metal wiring line.

In addition, as shown in FIG. 9, a narrowed width part 57, which has a wiring line width narrower than that of other region, is provided at a part of the gate wiring line 40. Like wise, a similar narrowed width part is also provided to a part, which intersects with the gate wiring line 40, of the source wiring line 42. As a result, capacitance is not stored at the intersection since each wiring width of the gate wiring line 40 and the source wiring line 42 is formed narrow at their intersection.

A Method for Forming a Pixel

FIGS. 10A through 10E are sectional views, which are taken along the line C-C′ shown in FIG. 9, illustrating forming steps of the pixel structure 250. The method for forming a film pattern can be employed in forming the pixel electrode.

As shown in FIG. 10A, a gate insulation film 39 (insulation film) is formed on the surface of the bank 34, which includes the gate electrode 41 formed by the above-described method, by a plasma CVD method or the like. Here, the gate insulation film 39 is made of silicon nitride.

In this case, the curvature factor of the curved surface 34c, which is shown in FIG. 3B, of the bank 34 is set based on the insulation characteristic of the gate insulation film 39. The angle that the curved surface 34c makes with respect to the surface of the gate electrode 41 is 45 degrees or less. Thus, the gate insulation film 39 smoothly covers the bank 34 and the gate electrode 41 along the surface of the gate electrode 41 without a bending that causes a stress concentration even in a case where the end of the surface of the gate electrode 41 forms a concave shape as shown in FIG. 3B. The concave shape is actually formed due to surface tension of the functional liquid while FIG. 7D shows that the surface of the gate electrode 41 and the surface of the second bank layer 36 are on nearly the same plane.

Then, an active layer is formed on the gate insulation film 39.

Subsequently, a predetermined shape is patterned by a photolithographic treatment and etching, thereby an amorphous silicon film 46 is formed as shown in FIG. 10A.

Then, on the amorphous silicon film 46, a contact layer 47 is formed. Subsequently, a predetermined shape is patterned by photolithographic and etching as shown in FIG. 10A. The contact layer 47 is formed as an n+-type silicon film by changing raw material gas or plasma conditions.

Then, as shown in FIG. 10B, a bank material is coated on the entire surface including the contact layer 47 by a spin coating method or the like. In this case, various methods such as spray coating, roll coating, die coating, dip coating, and an inkjet method can be applied as the coating method of the bank forming materials. Here, as the material included in the bank material, polymer material such as an acrylate resin, a polyimide resin, an olefin resin, and a melamine resin is used since the material needs to have optical transparency and lyophobicity after a bank is formed. More preferably, a bank forming material having a siloxane bond is used in terms of its heat resistance in a firing process and optical transparency. Then, CF₄ plasma treatment or the like (plasma treatment using gas containing a fluorine component) is carried out to give lyophobicity to the bank material. Alternatively, a raw material for forming a bank may be filled with a lyophobic component (a fluorine group or the like) instead of such treatment. In this case, CF₄ plasma treatment or the like can be omitted.

Next, a bank 34d for source-drain electrode, whose width is 1/20 to 1/10 of one pixel pitch, is formed. Specifically, a source electrode forming region 43a is formed by a photolithographic treatment to a position, which corresponds to the source electrode 43, of the bank forming material coated on the upper surface of the gate insulation film 39. Likewise, a drain electrode forming region 44a is formed to a position corresponding to the drain electrode 44.

A bank similar to the bank 34, which has a multilayered structure of the first bank layer 35 and the second bank layer 36 as described in the aforementioned embodiment, can be formed and used as the bank 34d for source-drain electrode. That is, the method for forming a metal wiring line according to the invention can be applied to the steps to form the source and drain electrodes.

Accordingly, the multilayered structure allows a functional liquid to wet and spread adequately, thereby a source electrode and drain electrode can be uniformly and homogeneously formed. The multilayered structure includes the first bank layer 35 having a contact angle of less than 50 degrees with respect to a functional liquid, and the second bank layer 36 having a contact angle larger than that of the first bank layer 35. Especially, when a multilayered structure composed of a plurality of materials (manganese, silver, and nickel) is employed to a source electrode and a drain electrode, manufacturing efficiency can be increased since performing a lyophobic treatment for a bank is not required at every time when each of a plurality of metal wiring lines is layered.

Then, the functional liquid is disposed to the source electrode forming region 43a and the drain electrode forming region 44a that are formed in the bank 34d so as to form the source electrode 43 and the drain electrode 44. Specifically, first, the functional liquid is disposed to a region for forming a source wiring line by the droplet discharge device IJ. This step is not shown. The width H5 of the source electrode forming region 43a is formed so as to be narrower than the width H6 of the region for forming a source wiring line as shown in FIG. 9. Therefore, the functional liquid disposed to the region for forming a source wiring line is transiently blocked by the narrowed width part provided to the source wiring line, flowing into the source electrode forming region 43a by a capillary phenomenon. As a result, as shown in FIG. 10C, the source electrode 43 is formed. Likewise, the drain electrode 44 is formed by discharging the functional liquid to the drain electrode forming region 44a. This step is not shown.

As shown FIG. 10C, the bank 34d is removed after forming the source electrode 43 and the drain electrode 44. Then, the n⁺-type silicon film, which forms the contact layer 47, formed between the source electrode 43 and the drain electrode 44 is etched by using each of the source electrode 43 and the drain electrode 44 that remain on the contact layer 47 as a mask. In the etching step, the n⁺-type silicon film of the contact layer 47 formed between the source electrode 43 and the drain electrode 44 is removed. As a result, a part of the amorphous silicon film 46, which is formed under the n⁺-type silicon film, is exposed. Consequently, the source region 32 made of n⁺-type silicon is formed under the source electrode 43, while the drain region 33 made of n⁺-type silicon is formed under the drain electrode 44. Under the source region 32 and the drain region 33, a channel region made of the amorphous silicon film 46 is formed.

Through the above-described steps, the TFT 30 of a bottom gate type is achieved.

As shown in FIG. 10D, a passivation film 38 (protective film) is formed on the source electrode 43, the drain electrode 44, the source region 32, the drain region 33, and the amorphous silicon film 46 that has been exposed, by vapor deposition, sputtering or the like. Subsequently, the passivation film 38 on the gate insulation film 39 on which the pixel electrode 45 is formed, is removed by a photolithographic treatment and etching. At the same time, a contact hole 49 is formed to the passivation film 38 formed on the drain electrode 44 in order to electrically connect the pixel electrode 45 to the source electrode 43.

Then, as shown in FIG. 10E, a bank material is coated on the entire surface including the gate insulation film 39 on which the pixel electrode 45 is formed. Here, the bank material includes a material such as an acrylate resin, a polyimide resin, or polysilazane as described above. Subsequently, a lyophobic treatment is carried out on the upper surface of the bank material (a pixel electrode bank 34e) by plasma treatment or the like. Then, the pixel electrode bank 34e that partitions a region in which the pixel electrode 45 is formed, is formed by a photolithographic treatment.

A bank having a multilayered structure used in the method for forming a metal wiring line according to the invention is more preferably formed as the pixel electrode bank 34e. If the side surface has lyophobicity with respect to ink, pixel electrode forming ink is easily repelled on the bank when it is contacted and droplets easily form a convex shape. Thus, a condition setting of the drying and firing treatments is needed to make the coated droplet shape flat.

Next, the pixel electrode 45 made of indium tin oxide (ITO) is formed in the region for forming a pixel electrode, which is partitioned by the pixel electrode bank 34e, by an ink-jet method, a vapor deposition method, or the like. In addition, the contact hole 49 is filled with the pixel electrode 45 so as to assure an electrical connection between the pixel electrode 45 and the drain electrode 44. In the embodiment, a lyophobic treatment is carried out on the upper surface of the pixel electrode bank 34e, and a lyophilic treatment is carried out to the region for forming a pixel electrode. Accordingly, the pixel electrode 45 can be formed without running over the region for forming a pixel electrode.

Through the above-described steps, the pixel of the embodiment shown in FIG. 9 can be formed.

As described above, in the embodiment, the step, in which one droplet of a functional liquid is coated and fired, is repeated in forming the gate wiring line 40 and the gate electrode 41. The gate wiring line 40 and the gate electrode 41 can be formed that have flatness superior to a case where required droplets are fired at one time after their coating. Particularly, in the embodiment, the volume of one droplet coated in the region 55 satisfies that the gate wiring line 40 is flatter than the gate electrode 41, enabling the flatness of the gate electrode 41 to be more improved.

Also, in the embodiment, the bank 34 is composed of the first bank layer 35 having lyophilicity and the second bank layer 36 having lyophobicity. Even if the droplet of a functional liquid is landed on the upper surface of the second bank layer 36 when the functional liquid is coated, the functional liquid is repelled and guided to the pattern forming region 13 (mainly, the first pattern forming region). Further, since the first bank layer 35 has lyophilicity, the functional liquid wets favorably to the first bank layer 35, whereby the functional liquid can easily wet and spread in the second pattern forming region along the first bank layer 35.

Also, in the embodiment, the angle that the curved surface 34 c of the bank 34 makes with respect to the surface of the gate electrode 41 (the gate wiring line 40) is set based on the insulation characteristic of the gate insulation film 39, enabling an insulation breakdown induced by an electric field concentration due to an edge effect of the gate electrode 41 (the gate wiring line 40) to be prevented. As a result, a high quality device can be achieved that performs desired characteristics with the insulation secured.

Electro-Optical Device

Next, a liquid crystal display will be described. The liquid crystal display is an example of an electro-optical device according to a third embodiment of the invention. The electro-optical device is provided with a pixel (device) of the second embodiment.

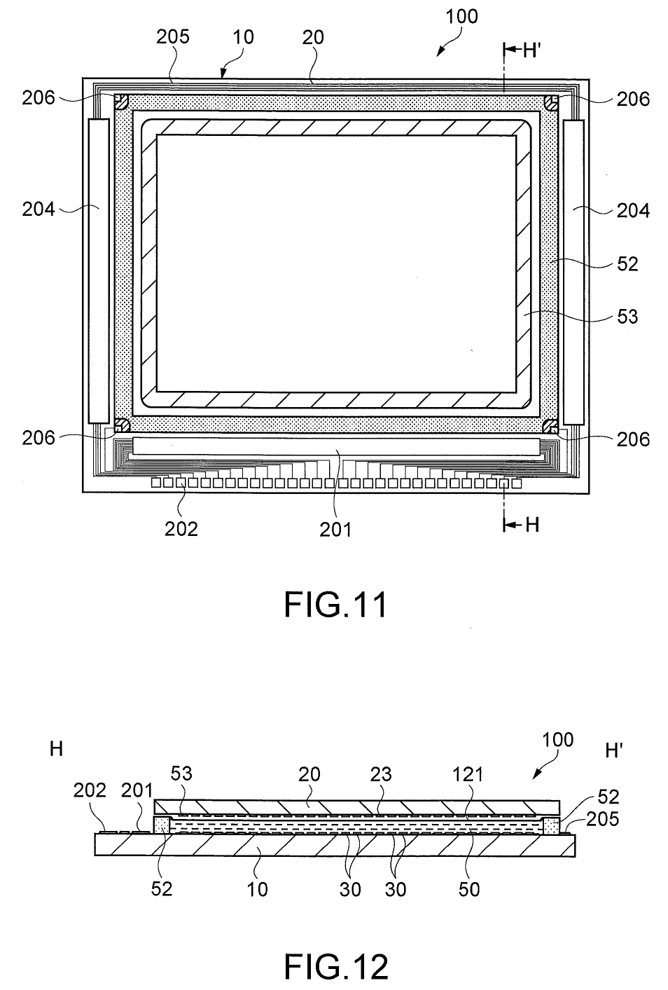

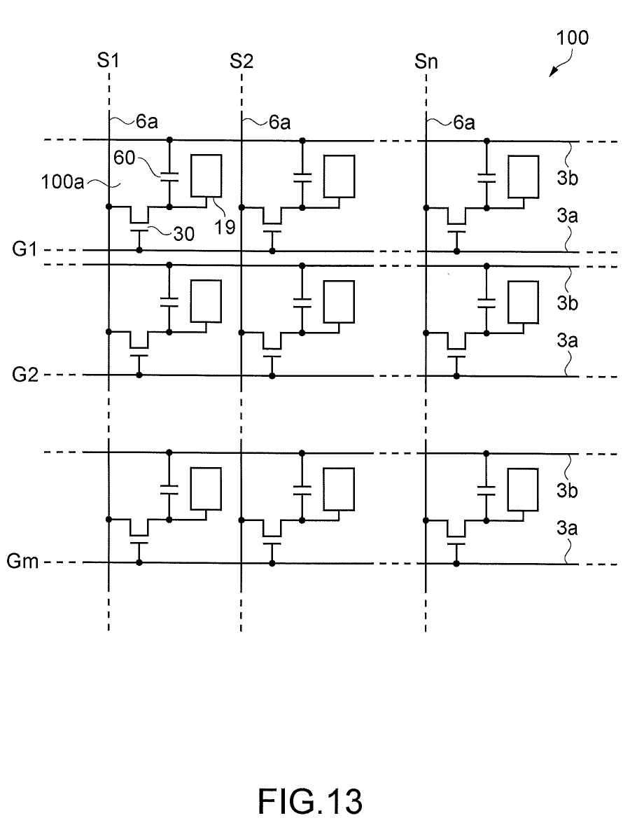

FIG. 11 is a plan view of a liquid crystal display of the third embodiment. The plan view illustrates each element by viewing from a counter substrate side. FIG. 12 is a sectional view taken along the line H-H′ of FIG. 11. FIG. 13 is an equivalent circuit diagram illustrating a plurality of pixels, which include various elements, wiring lines, and the like, formed in a matrix in an image display area of a liquid crystal display. Note that scales of layers and members in the drawings referred to hereinafter are adequately changed so that they are visible.

Referring to FIGS. 11 and 12, in a liquid crystal display (electro-optical device) 100, a TFT array substrate 10 and a counter substrate 20 are bonded as a pair with a photocuring sealant 52 interposed therebetween. In an area defined by the sealant 52, a liquid crystal 50 is sealed and retained.

In a region inside the area where the sealant 52 is provided, a peripheral light-blocking film 53 made of a light blocking material is provided. In an area outside the sealant 52, a data line driving circuit 201 and a mount terminal 202 are provided along one side of the TFT array substrate 10. Provided along two sides adjacent to the one side are scanning line driving circuits 204. Provided along another side of the TFT array substrate 10 are a plurality of wiring lines 205 to connect the scanning line driving circuits 204 provided to the both sides of an image display area. At one or more of the corners of the counter substrate 20, an inter-substrate conductive material 206 is disposed to provide electrical conductivity between the TFT array substrate 10 and the counter substrate 20.

In this regard, instead of providing the data line driving circuit 201 and the scanning line driving circuits 204 on the TFT array substrate 10, a tape automated bonding (TAB) substrate on which a driving LSI is mounted and the TFT array substrate 10 may be electrically and mechanically connected with an anisotropic conductive film, which is provided between a group of terminals provided around the TFT array substrate 10 and the TAB substrate. Note that a retardation film, a polarizer, etc., included in the liquid crystal display 100 are disposed in a predetermined direction (not shown) depending on the type of the liquid crystal 50, i.e., operation modes including twisted nematic (TN), a C-TN method, a VA method, and an IPS method, and normally white mode or normally black mode.

If the liquid crystal display 100 is provided as a color display, red (R), green (G) and blue (B) color filters, for example, and their protective films are provided in an area in the counter substrate 20 facing each pixel electrode in the TFT array substrate 10 that will be described below.

In the image display area of the liquid crystal display 100 of having the above structure, as shown in FIG. 13, a plurality of pixels 100a are arranged in a matrix. Each of the pixels 100a is provided with the TFT (switching element) 30 for switching a pixel. To the source of the TFT 30, each of data lines 6a that supply pixel signals S1 through Sn is electrically coupled. The pixel signals S1 through Sn written in respective data lines 6a may be supplied line-sequentially in this order or in groups of adjacent data lines 6a. To the gate of the TFT 30, each of scanning lines 3a is electrically coupled. To respective scanning lines 3a, scanning signals G1 through Gm are applied pulsatively and line-sequentially in this order at a predetermined timing.

A pixel electrode 19 is electrically coupled to the drain of the TFT 30. The TFT 30, which is a switching element, is turned on for a certain period, and thereby the pixel signals S1 through Sn supplied from the data line 6a are written in respective pixels at a predetermined timing. Each of The pixel signals S1 through Sn, which has a predetermined level and written in liquid crystal via the pixel electrode 19, is retained between a counter electrode 121 of the counter substrate 20 shown in FIG. 12 and the pixel electrode 19 for a certain period. In order to prevent a leak of the pixel signals S1 through Sn that are retained, a storage capacitor 60 is provided in parallel with a liquid crystal capacitance formed between the pixel electrode 19 and the counter electrode 121. For example, the voltage of the pixel electrode 19 is retained by the storage capacitor 60 for a period of time three orders of magnitude longer than the time for which a source electrode is applied. Consequently, an electron retention property increases, thereby a liquid crystal display 100 having a high contrast ratio can be provided.

Provided with the above device, the liquid crystal display 100 of the embodiment can achieve high quality that no defects occur.

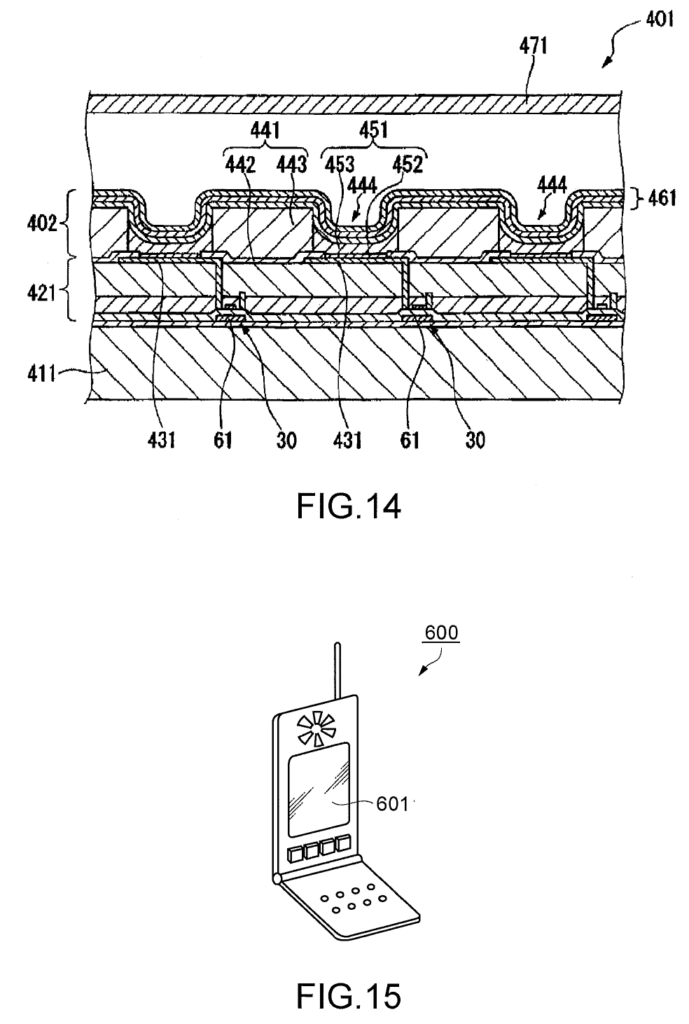

FIG. 14 is a sectional view illustrating an organic EL device provided with a pixel of the second embodiment. The schematic structure of the organic EL device will be described below with reference to FIG. 14.

In FIG. 14, an organic EL device 401 is provided with an organic EL element 402, substrate 411, a circuit element part 421, a pixel electrode 431, a sealing substrate 471, connected to a wiring line of a flexible substrate (not shown) and a driving IC (not shown). The organic EL element 402 includes a bank part 441, a light emitting element 451, and a cathode 461 (counter electrode). In the circuit element part 421, the TFT 30 serving as an active element is formed on the substrate 411. Arrayed on the circuit element part 421 is a plurality of pixel electrodes 431. The gate wiring line 61, which is included in the TFT 30, is formed by the method for forming a metal wiring line of the first embodiment.

Between the respective pixel electrodes 431, the bank parts 441 are formed as a grid like. The light emitting element 451 is formed to a concave opening 444 resultingly formed by the bank part 441. The light emitting element 451 is provided with an element emitting red light, an element emitting green light, and an element emitting blue light so that the organic EL device 401 provides a full-color display. The cathode 461 is formed on the entire upper surface of the bank parts 441 and the light emitting elements 451, and on the cathode 461, the sealing substrate 471 is placed.

A manufacturing process of the organic EL device 401 having an organic EL element includes a bank part forming step to form the bank part 441, a plasma treatment step to adequately form the light emitting element 451, a light emitting element forming step to form the light emitting element 451, a counter electrode forming step to form the cathode 461, and a sealing step to place the sealing substrate 471 on the cathode 461 and seal it.

In the light emitting element forming step, the light emitting element 451 is formed by forming a hole injection layer 452 and a light emitting layer 453 on the pixel electrode 431, which is located under the concave opening 444. The step also includes a hole injection layer forming step and a light emitting layer forming step. The hole injection layer forming step includes a first discharge step and a first drying step. In the first discharge step, a liquid material to form the hole injection layer 452 is discharged onto each pixel electrode 431. In the first drying step, the discharged liquid material is dried so as to form the hole injection layer 452. The light emitting layer forming step includes a second discharge step and a second drying step. In the second discharge step, a liquid material to form the light emitting layer 453 is discharged onto the hole injection layer 452. In the second drying step, the discharged liquid material is dried so as to form the light emitting layer 453. As for the light emitting layer 453, three types of layers are formed by materials, each corresponding to respective three colors of red, green, and blue as described above. Therefore, the second discharge step includes three steps, each discharging respective three types of materials.

Since the electro-optical device according to the invention is provided with a device having high quality, an electro-optical device having improved quality and performance can be achieved.

The electro-optical device according to the invention is also applicable to plasma display panels (PDPs) and surface-conduction electron emission elements that use a phenomenon of emitting electrons by passing an electrical current through in parallel with the surface of a thin film formed on a substrate with a small area.

Electronic Apparatus

Next, specific examples of an electronic apparatus according to a fourth embodiment of the invention will be described.

FIG. 15 is a perspective view illustrating an example of a cellular phone. In FIG. 15, a cellular phone body 600 (electronic apparatus) is provided with a liquid crystal display 601 including a liquid crystal display of the third embodiment.

The electronic apparatus shown in FIG. 15 provides high quality and performance since it is provided with the liquid crystal display of the third embodiment.

The electronic apparatus of the embodiment is equipped with a liquid crystal device, but alternatively it can be equipped with another electro-optical device such as an organic electroluminescent display and a plasma display.

In addition to the electronic apparatuses described above, the embodiment can be applied to various electronic apparatuses. Examples of these electronic apparatuses include: liquid crystal projectors, personal computers (PCs) and engineering work stations (EWS) for multimedia applications, pagers, word processors, televisions, video recorders of viewfinder types or direct monitor types, electronic notebooks, electric calculators, car navigations systems, point-of-sale (POS) terminals, and apparatuses equipped with a touch panel.

While the preferred embodiments according to the invention are described referring to the accompanying drawings, it is understood that the invention is not limited to these examples. The shapes, combinations and the like of each component member described in the foregoing embodiments are illustrative only, and various modifications may be made based on design requirement and the like within the scope of the invention.

For example, a bank structure having a desired pattern is formed by a lithographic treatment or etching in the above-described embodiments. Alternatively, a desired pattern may be formed by patterning with laser instead of the above forming method.

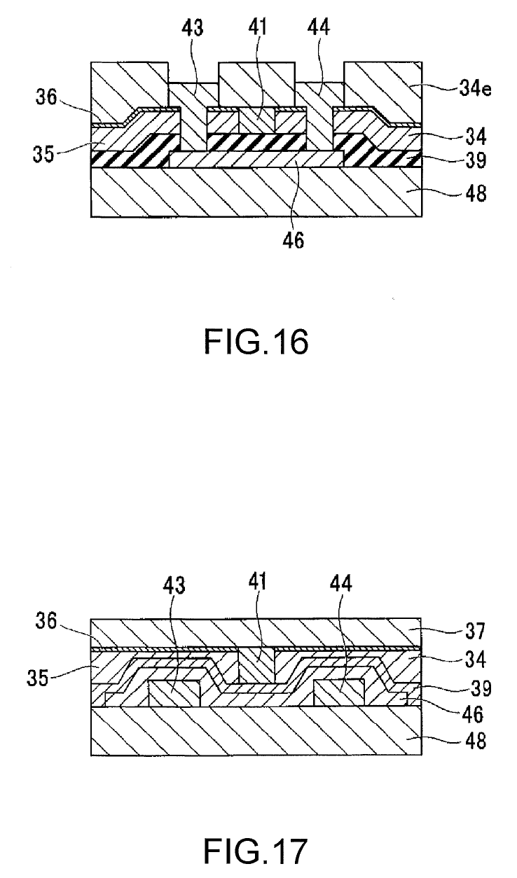

The method for manufacturing a metal wiring line of the first embodiment also can be applied to manufacture an active matrix substrate as shown in FIGS. 16 and 17. Specifically, FIG. 16 is a schematic sectional view illustrating an example of an active matrix substrate including a transistor of a coplanar structure. In the substrate, an amorphous silicon film 46 is formed on a substrate 48, and the gate electrode 41 is formed on the amorphous silicon film 46 with the gate insulation film 39 interposed therebetween. The bank 34 surrounds the gate electrode 41 so as to define the pattern of the gate electrode 41. The bank 34 also functions as an interlayer insulation layer. Formed to the bank 34 and the gate insulation film 39 are contact holes as viewed in FIG. 14. The source electrode 43 is formed so as to connect to a source region of the amorphous silicon film 46 through one contact hole, while the drain electrode 44 is formed so as to connect to a drain region of the amorphous silicon film 46 through the other contact hole. To the drain electrode 44, a pixel electrode is connected.

FIG. 17 is a schematic sectional view illustrating an example of an active matrix substrate including a transistor of a stagger structure. In the structure, the source electrode 43 and the drain electrode 44 are formed on the substrate 48, and the amorphous silicon film 46 is formed on the source electrode 43 and the drain electrode 44. On the amorphous silicon film 46, the gate electrode 41 is formed with the gate insulation film 39 interposed therebetween. The bank 34 surrounds the gate electrode 41 so as to define the pattern of the gate electrode 41. The bank 34 also functions as an interlayer insulation layer. To the drain electrode 44, a pixel electrode is connected.

When manufacturing the above-described active matrix substrates, the method for forming a metal wiring line can be applied. That is, for example, when the gate electrode 41 is formed in a region surrounded by the bank 34, the gate electrode 41 can be formed with high reliability by applying the method for forming a metal wiring line according to the invention. Note that the method for forming a film pattern can be applied to processes to form not only a gate electrode, but also a source electrode, a drain electrode, and a pixel electrode.

What is claimed is:

1. A method for forming a metal wiring line, comprising:
(a) forming a bank including a first opening corresponding to a first film pattern and a second opening corresponding to a second film pattern that is coupled to the first film pattern and has a width narrower than a width of the first film pattern;
(b) disposing a droplet of a functional liquid in the first opening so as to dispose the functional liquid in the second opening by an autonomous flow of the functional liquid;
(c) hardening the functional liquid disposed in the first opening and the second opening; and
(d) forming the first film pattern and the second film pattern by alternately repeating step (b) and step (c) at least one time.

2. The method for forming a metal wiring line according to claim 1, wherein the bank includes a first bank layer having lyophilicity with respect to the functional liquid and a second bank layer having lyophobicity with respect to the functional liquid, the second bank layer being layered on the first bank layer.

3. The method for forming a metal wiring line according to claim 1, wherein a volume of the droplet disposed in the first opening at one time in step (b) satisfies that a liquid level of the first opening is one of equal to and lower than a liquid level of the second opening when the functional liquid flows in the second opening.

4. A device, comprising:
a substrate;
a bank formed on the substrate;
a wiring line forming region partitioned by the bank;
a metal wiring line that is formed by coating a droplet of a functional liquid in the wiring line forming region and hardening a coated functional liquid; and
an insulation film that covers the metal wiring line and the bank, wherein the bank includes an upper surface, a curved surface and a side surface facing the wiring line forming region, and the curved surface is formed between the upper surface and the side surface and makes an angle with respect to a surface of the metal wiring line, the angle being set based on an insulation characteristic of the insulation film.

5. The device according to claim 4, wherein the angle is 45 degrees or less.

6. The device according to claim 4, wherein the metal wiring line is formed by alternately repeating coating and hardening the functional liquid at least one time.

7. The device according to claim 4, wherein the bank includes a first bank layer having lyophilicity with respect to the functional liquid and a second bank layer having lyophobicity with respect to the functional liquid, the second bank layer being layered on the first bank layer.

8. An electro-optical device, comprising the device according to claim 4.

9. An electronic apparatus, comprising the electro-optical device according to claim 8.

10. A method for manufacturing an active matrix substrate, comprising:
(a) forming a gate wiring line on a substrate;
(b) forming a gate insulation film on the gate wiring line;
(c) depositing a semiconductor layer on the gate insulation film;
(d) forming a source electrode and a drain electrode on the gate insulation film;
(e) disposing an insulation material on the source electrode and the drain electrode; and
(f) forming a pixel electrode on the insulation material, wherein the method for forming a metal wiring line according to claim 1 is used in at least one of steps (a), (d) and (f).

11. A method for manufacturing an active matrix substrate, comprising:
(g) forming a source electrode and a drain electrode on a substrate;
(h) forming a semiconductor layer on the source electrode and the drain electrode;
(i) forming a gate electrode on the semiconductor layer with a gate insulation film interposed between the gate electrode and the semiconductor layer; and
(j) forming a pixel electrode so as to be coupled to the drain electrode, wherein the method for forming a metal wiring line according to claim 1 is used in at least one of steps (g), (i), and (j).

12. A method for manufacturing an active matrix substrate, comprising:
(k) forming a semiconductor layer on a substrate;
(l) forming a gate electrode on the semiconductor layer with a gate insulation film interposed between the gate electrode and the semiconductor layer;
(m) forming a source electrode so as to be coupled to a source region of the semiconductor layer through a first contact hole formed in the gate insulation film, and a drain electrode so as to be coupled to a drain region of the semiconductor layer through a second contact hole formed in the gate insulation film; and
(n) forming a pixel electrode so as to be coupled to the drain electrode, wherein the method for forming a metal wiring line according to claim 1 is used in at least one of steps (l), (m), and (n).
